(19) United States
(12) Patent Application Publication
(10) Pub. No.: US 2023/0110154 A1
(43) Pub. Date: Apr. 13, 2023

(54) SEMICONDUCTOR DEVICE

(71) Applicant: ROHM CO., LTD., Kyoto-shi, Kyoto (JP)

(72) Inventors: Bin ZHANG, Kyoto-shi, Kyoto (JP); Kenji FUJII, Kyoto-shi, Kyoto (JP); Akinori NII, Kyoto-shi, Kyoto (JP)

(21) Appl. No.: 17/911,101

(22) PCT Filed: Mar. 18, 2021
(86) PCT No.: PCT/JP2021/011035

§ 371 Date: Sep. 12, 2022

(30) Foreign Application Priority Data
Mar. 26, 2020 (JP) 2020-055651

(51) Int. Cl. H01L 21/50; H01L 23/13; H01L 23/495; H01L 23/00

(52) U.S. Cl. CPC H01L 21/50; H01L 23/13; H01L 23/49541; H01L 24/16; H01L 24/18; H01L 24/49; H01L 24/73; H01L 2224/16245; H01L 2924/181; H01L 2224/4903; H01L 2224/73265

(57) ABSTRACT

A semiconductor device includes a semiconductor element, a conducting member, a conductive bonding material, a resin member and a first barrier layer. The semiconductor element includes an element first surface and an element second surface facing away from each other in a thickness direction, with the element first surface provided with an electrode. The conducting member includes an obverse surface facing the element first surface and a reverse surface facing away from the obverse surface. The conductive bonding material is disposed between the electrode and the obverse surface of the conducting member. The resin member covers at least a portion of the conducting member, the semiconductor element and the conductive bonding material. The first barrier layer is disposed between the electrode and the conductive bonding material to prevent a reaction between the electrode and the conductive bonding material.

### TECHNICAL FIELD

The present disclosure relates to semiconductor devices.

### BACKGROUND ART

Conventionally, a semiconductor device having a semiconductor element attached to a lead by flip-chip mounting has been proposed.

For example, Patent document 1 discloses a semiconductor device that includes a semiconductor element having a plurality of electrodes, a plurality of leads, and a resin package covering the semiconductor element. The electrodes are soldered to the leads, so that the semiconductor element is flip-chip mounted on the leads.

### PRIOR ART DOCUMENTS

### Patent Documents

Patent Document 1: JP-A-2007-518282

### SUMMARY OF THE INVENTION

### Problem to be Solved by the Invention

Depending on the usage environment and/or operating conditions of the semiconductor device, the temperature of the semiconductor device may rise and fall repeatedly. During the temperature change, thermal stress may be induced due to the thermal expansion difference between, for example, the semiconductor element and the leads. Any crack caused by the thermal stress at the joint between solder and an electrode may affect the proper operation of the semiconductor device.

In view of the circumstances described above, an object of the present disclosure is to provide a semiconductor device designed to prevent the formation of a crack at the joint interface between solder and an electrode.

### Means to Solve the Problem

A semiconductor device provided by the present disclosure includes a semiconductor element, a conducting member, a conductive bonding material, a resin member and a first barrier layer. The semiconductor element includes an element first surface and an element second surface facing away from each other in a thickness direction, with the element first surface provided with an electrode. The conducting member includes an obverse surface facing the element first surface and a reverse surface facing away from the obverse surface. The conductive bonding material is disposed between the electrode and the obverse surface of the conducting member. The resin member covers at least a portion of the conducting member, the semiconductor element and the conductive bonding material. The first barrier layer is disposed between the electrode and the conductive bonding material and prevents the electrode and the conductive bonding material from reacting with each other.

Preferably, the electrode contains Cu.

Preferably, the conducting member contains Cu.

Preferably, the first barrier layer contains Ni.

Preferably, the conductive bonding material contains Sn.

Preferably, the electrode and the first barrier layer are in contact with each other.

Preferably, the conductive bonding material and the first barrier layer are in contact with each other.

Preferably, the semiconductor device further includes a second barrier layer that is disposed between the conducting member and the conductive bonding material and prevents the conducting member and the conductive bonding material from compounding with each other.

Preferably, the second barrier layer contains Ni.

Preferably, the second barrier layer includes a base layer, and an auxiliary layer disposed between the conductive bonding material and the base layer.

Preferably, the conducting member and the second barrier layer are in contact with each other.

Preferably, the conductive bonding material and the second barrier layer are in contact with each other.

Preferably, the second barrier layer is larger than the first barrier layer as viewed in the thickness direction.

Preferably, the electrode includes a lateral surface facing in a direction perpendicular to the thickness direction.

### Advantages of Invention

According to the configuration described above, the semiconductor device is configured prevent the formation of a crack at the joint interface between solder and an electrode.

Other features and advantages of the present disclosure will be more apparent from the detailed description given below with reference to the accompanying drawings.

### BRIEF DESCRIPTION OF THE DRAWINGS

FIG. 1 is a perspective view of a semiconductor device according to a first embodiment.

FIG. 2 is a plan view of the semiconductor device shown in FIG. 1 (with a sealing resin shown transparent).

FIG. 3 is a plan view of the semiconductor device shown in FIG. 1 (with a semiconductor element and the sealing resin shown transparent).

FIG. 4 is a bottom view of the semiconductor device shown in FIG. 1.

FIG. 5 is a front view of the semiconductor device shown in FIG. 1.

FIG. 6 is a rear view of the semiconductor device shown in FIG. 1.

FIG. 7 is a right-side view of the semiconductor device shown in FIG. 1.

FIG. 8 is a left-side view of the semiconductor device shown in FIG. 1.

FIG. 9 is a sectional view taken along line IX-IX of FIG. 3.

FIG. 10 is a sectional view taken along line X-X of FIG. 3.

FIG. 11 is a sectional view taken along line XI-XI of FIG. 3.

FIG. 12 is a sectional view taken along line XII-XII of FIG. 3.

FIG. 13 is an enlarged view showing a portion (around a first electrode) of FIG. 9.

FIG. 14 is an enlarged sectional view taken along line XIV-XIV of FIG. 13.

FIG. 15 is an enlarged view showing a portion (around a second electrode) of FIG. 9.

FIG. 16 is an enlarged sectional view showing a portion of a semiconductor device according to a first variation of the first embodiment.

FIG. 17 is an enlarged sectional view showing a portion of a semiconductor device according to a second embodiment.

### MODE FOR CARRYING OUT THE INVENTION

Embodiments of the present disclosure are described below with reference to the drawings.

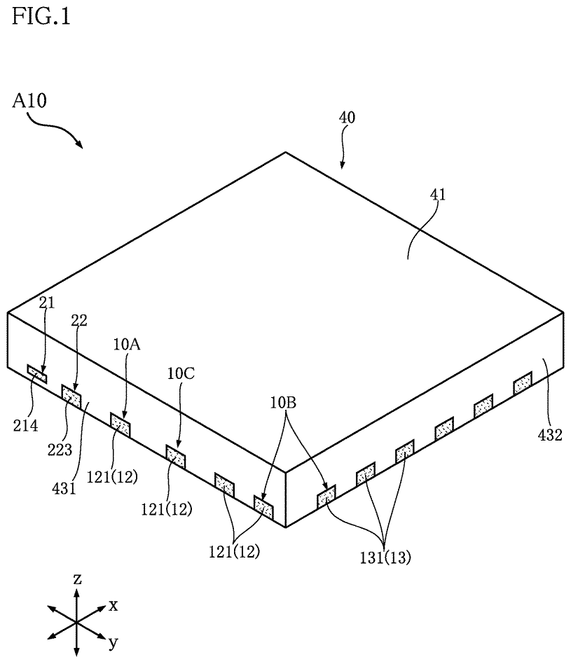

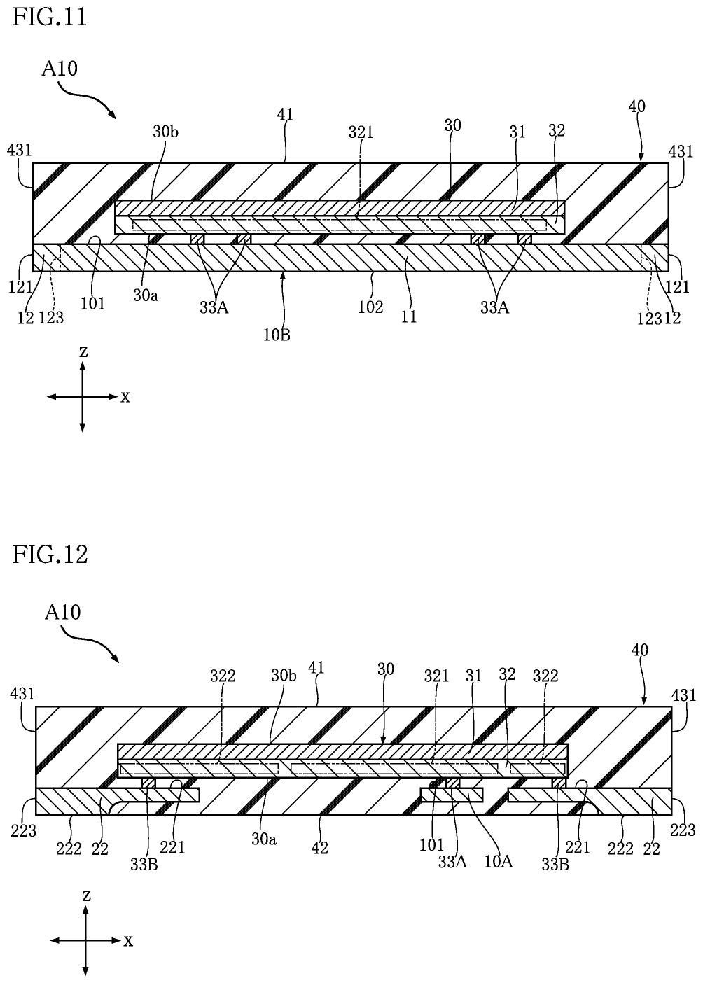

With reference to FIGS. 1 to 15, a semiconductor device A10 according to a first embodiment is described. The semiconductor device A10 includes a plurality of first leads 10A, 10B and 10C, a plurality of second leads 21, a pair of third leads 22, a semiconductor element 30, a conductive bonding material 70 and a sealing resin 40. As shown in FIG. 1, the semiconductor device A10 is in a QFN (quad flat non-leaded) package in this embodiment but the package type is not limited to this. The application and function of semiconductor device A10 are not limited either. Application of the semiconductor device A10 can include electronic devices, general industrial devices and vehicle-mount devices. Function of the semiconductor device A10 can include DC/DC conversion and AC/DC conversion. This embodiment describes the semiconductor device A10 configured as a vehicle-mount DC/DC converter. The illustrated semiconductor device A10 is substantially square as viewed in the z direction (i.e., in plan view) but the present disclosure is not limited to this shape.

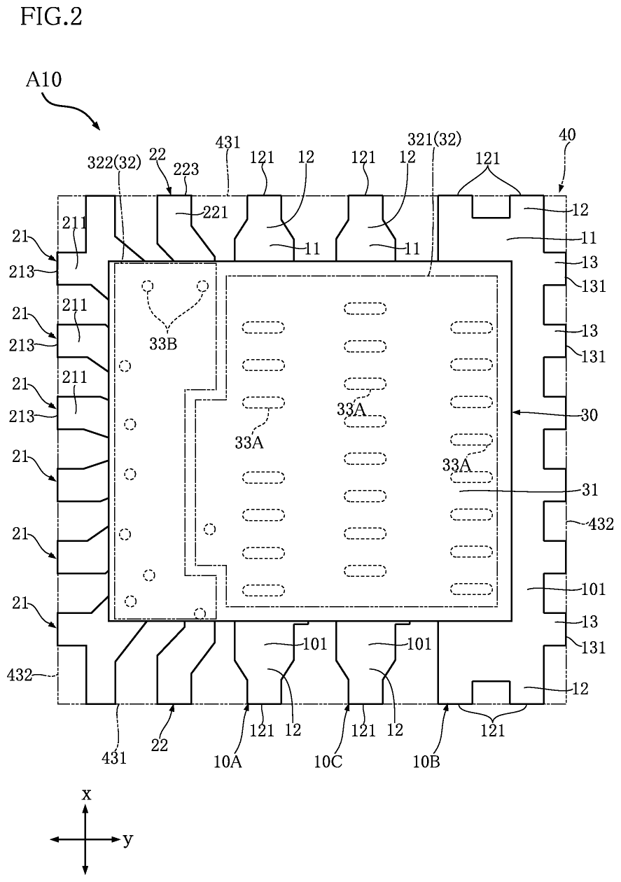

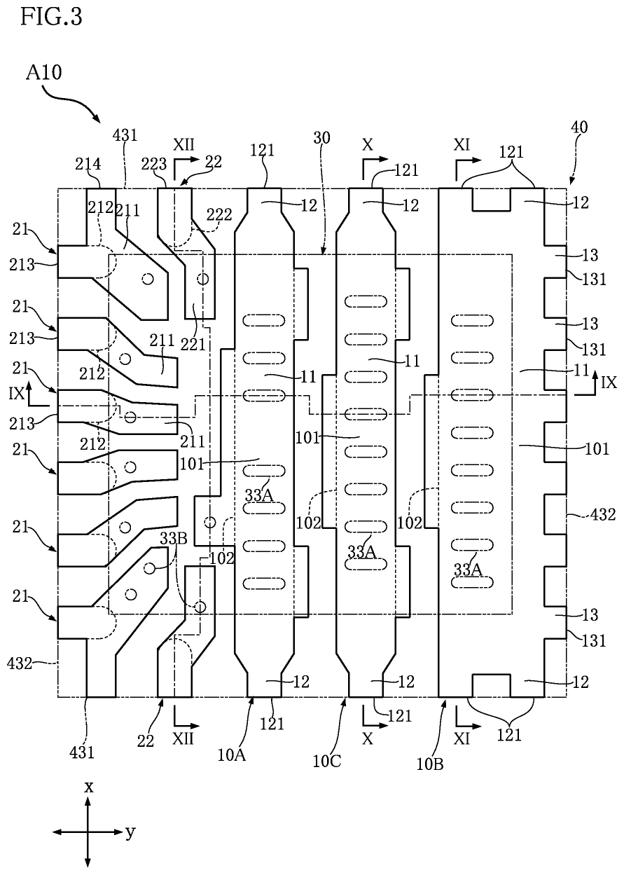

For convenience, FIG. 2 shows the sealing resin 40 as transparent. Similarly, FIG. 3 shows the semiconductor element 30 and the sealing resin 40 as transparent. In these figures, the semiconductor element 30 and the sealing resin 40 are shown in phantom lines (double-dotted lines). In the present disclosure, the z direction may be referred to also as the thickness direction. The x and y directions are perpendicular to the z direction and also to each other.

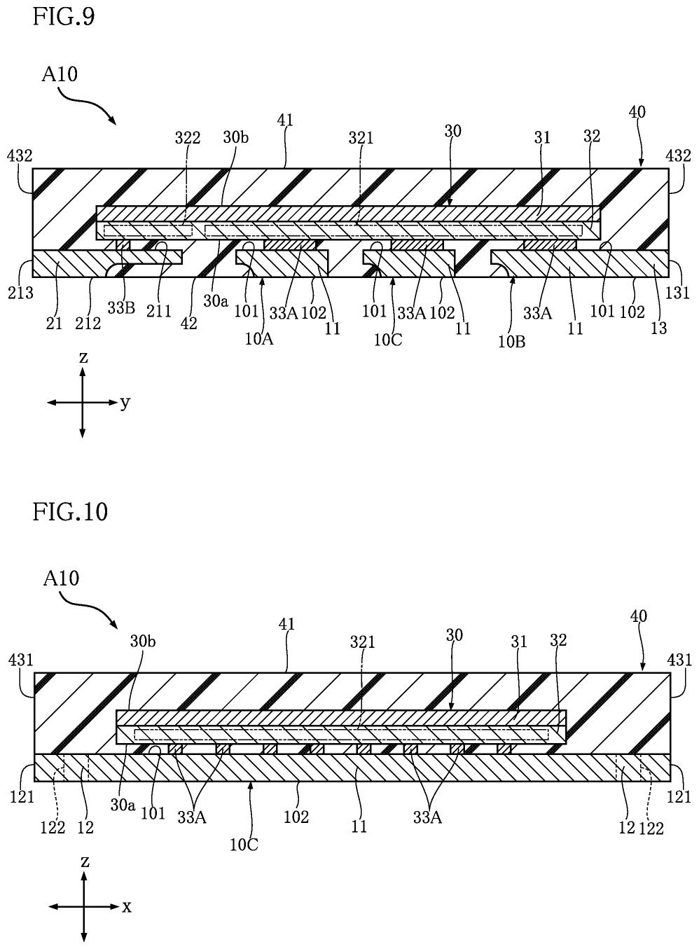

As shown in FIG. 2, the first leads 10A, 10B and 10C, the second leads 21 and the third leads 22 support the semiconductor element 30 and provide terminals for mounting the semiconductor device A10 on a wiring circuit board. The first leads 10A, 10B and 10C, the second leads 21 and the third leads 22 are examples of “conducting members”. As shown in FIGS. 9 to 12, the first leads 10A, 10B and 10C, the second leads 21 and the third leads 22 are partly covered with the sealing resin 40. In FIGS. 1 and 4 to 8, the exposed portions of the first leads 10A, 10B and 10C, the second leads 21 and the third leads 22 from the sealing resin 40 are shaded with dots.

The first leads 10A, 10B and 10C, the second leads 21 and the third leads 22 are made of Cu or an alloy of Cu.

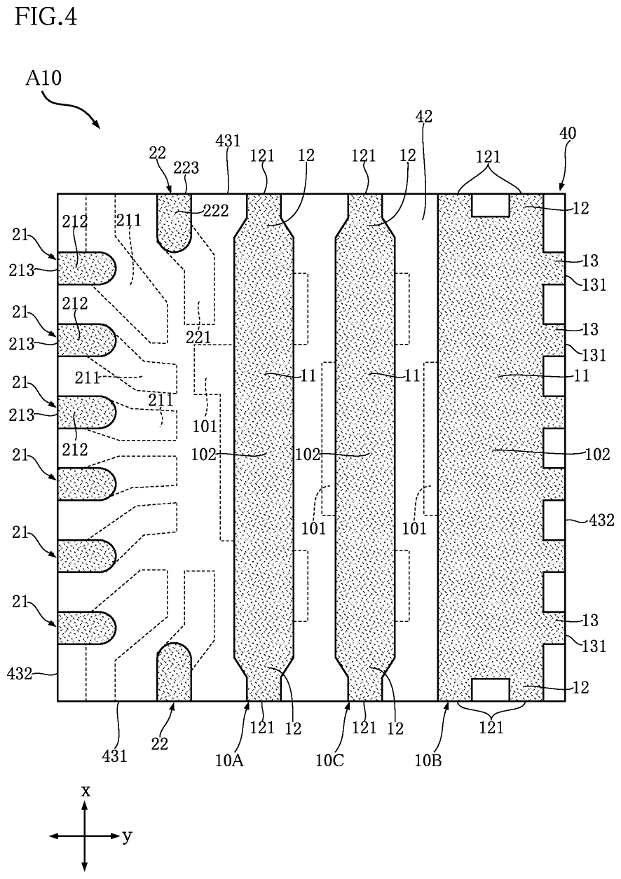

As shown in FIGS. 3 and 4, each of the first leads 10A, 10B and 10C is shaped like a strip extending in the x direction as viewed in the z direction. Each of the first leads 10A, 10B and 10C has a first obverse surface 101 and a first reverse surface 102 facing away from each other in the z direction. The first obverse surface 101 faces in a first sense of the z direction and opposes the semiconductor element 30. The first obverse surface 101 is an example of “obverse surface”. The first obverse surface 101 is covered with the sealing resin 40. The first reverse surface 102 faces in a second sense of the z direction. The first reverse surface 102 is exposed from the sealing resin 40 and is an example of “reverse surface”. Each of the first leads 10A, 10B and 10C has a main section 11, and the semiconductor element 30 is supported on the first obverse surfaces 101 of the respective main sections 11. As shown in FIGS. 3 and 4, each of the first leads 10A, 10B and 10C of the illustrated example has the first obverse surface 101 that is larger in area than the first reverse surface 102.

As shown in FIG. 3, the first leads 10A and 10B are for receiving a direct current power (voltage) to be converted by the semiconductor device A10. According to this embodiment, the first lead 10A is a positive electrode (P terminal), and the first lead 10B is a negative electrode (N terminal). The first lead 10C outputs alternating current power (voltage) converted by a later-described switching circuit 321 of the semiconductor element 30. The first leads 10A, 10B and 10C are arranged side by side in the y direction and in the order of the first leads 10A, 10C and 10B from a side in a first sense of the y direction to a side in a second sense of the y direction.

As shown in FIG. 3, the first lead 10A is located between the plurality of second leads 21 and the first lead 10C in the y direction. The first lead 10C is located between the first lead 10A and the first lead 10B in the y direction. Each of the first leads 10A and 10C includes the main section 11 and a pair of side sections 12. As shown in FIGS. 3 and 4, the main section 11 is elongated in the x direction. The side sections 12 are connected to the opposite ends of the main section 11 in the x direction and are narrower in the y direction than the main section 11. As shown in FIGS. 10 and 11, each side section 12 has a first end surface 121. The first end surface 121 is connected to the first obverse surface 101 and the first reverse surface 102 and faces in the x direction. The first end surface 121 is exposed from the sealing resin 40.

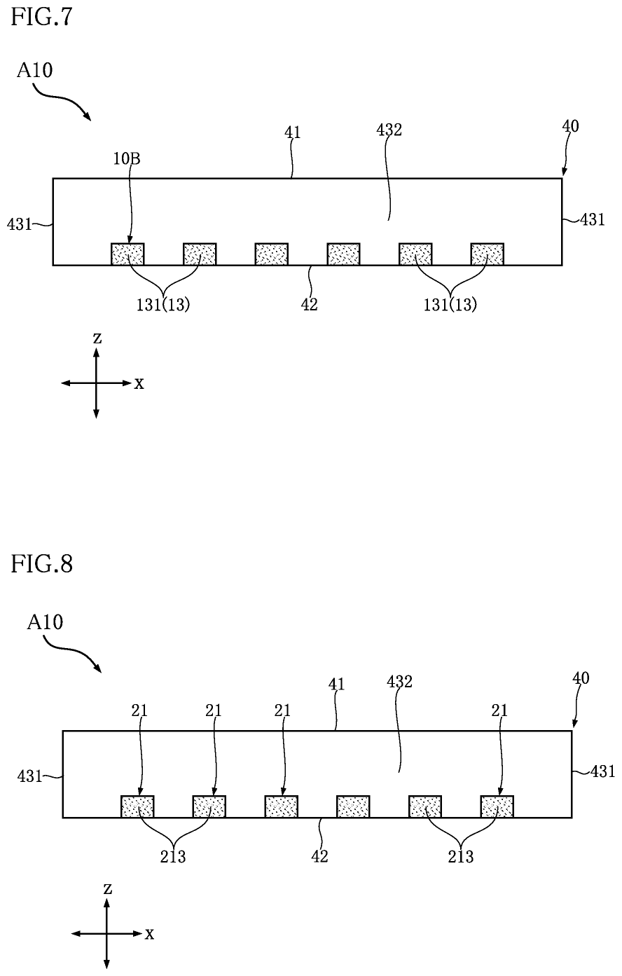

As shown in FIG. 3, the first lead 10B includes the main section 11, a pair of side sections 12 and a plurality of projections 13. Each projection 13 projects from the main section 11 in the second sense of the y direction. The spaces between adjacent projections 13 are filled with the sealing resin 40. Each projection 13 includes a sub-end surface 131. The sub-end surface 13 is connected to the first obverse surface 101 and the first reverse surface 102 and faces in the second sense of the y direction. The sub-end surface 131 is exposed from the sealing resin 40. As shown in FIG. 7, the respective sub-end surfaces 131 are arranged at predetermined intervals in the x direction. The first leads 10A, 10B and 10C are not required to have the shape formed with the main section 11 and the side sections 12 and may have a different shape.

The first leads 10A, 10B and 10C may plated with Sn (tin) to cover the first reverse surfaces 102, the first end surfaces 121, and the sub-end surfaces 131, which are exposed from the sealing resin 40. Instead of the Sn plating, plating with a plurality of metals, such as Ni, Pd and Au stacked in the stated order, may be used.

As shown in FIG. 3, the second leads 21 are offset from the first leads 10 in the first sense of the y direction. One of the second leads 21 is a ground terminal of a later-described control circuit 322 of the semiconductor element 30. The other second leads 21 are for receiving electric power (voltage) to drive the control circuit 322 or an electric signal to be transmitted to the control circuit 322. As shown in FIGS. 3 and 4, each second lead 21 has a second obverse surface 211, a second reverse surface 212 and a second end surface 213. The shapes of the second leads 21 are not limited.

The second obverse surface 211 of each second lead 21 faces in the same direction as the first obverse surfaces 101 of the first leads 10 in the z direction and opposes the semiconductor element 30. The second obverse surface 211 is covered with the sealing resin 40 and is an example of “obverse surface”. The semiconductor element 30 is supported on the second obverse surface 211. The second reverse surface 212 faces away from the second obverse surface 211. The second reverse surface 212 is exposed from the sealing resin 40 and is an example of “reverse surface”. The second end surface 213 is connected to the second obverse surface 211 and the second reverse surface 212 and faces in the first sense of the y direction. The second end surface 213 is exposed from the sealing resin 40. As shown in FIG. 8, the respective second end surfaces 213 are arranged at predetermined intervals in the x direction. Each of the two outermost second leads 21 in the x direction additionally has a fourth end surface 214 facing in the x direction. The fourth end surface 214 is exposed from the sealing resin 40. In the example shown in FIGS. 3 and 4, each second lead 21 has the second obverse surface 211 that is larger in area than the second reverse surface 212.

The second leads 21 may be plated with Sn to cover the second reverse surfaces 212, the second end surfaces 213 and the fourth end surfaces 214, which are exposed from the sealing resin 40. Instead of the Sn plating, plating with a plurality of metals, such as Ni, Pd and Au stacked in the stated order, may be used.

As shown in FIG. 3, the pair of third leads 22 are located between the first lead 10A and the plurality of second leads 21 in the y direction. The third leads 22 are spaced apart from each other in the x direction. Each third leads 22 is for receiving an electric signal to be transmitted to the control circuit 322 formed in the semiconductor element 30. As shown in FIGS. 3 and 4, each third lead 22 has a third obverse surface 221, a third reverse surface 222 and a third end surface 223. The shapes of the third leads 22 are not limited.

The third obverse surface 221 of each third lead 22 faces in the same direction as the first obverse surfaces 101 of the first leads 10 in the z direction and opposes the semiconductor element 30. The third obverse surface 221 is covered with the sealing resin 40 and is an example of “obverse surface”. The semiconductor element 30 is supported on the third obverse surface 221. The third reverse surface 222 faces away from the third obverse surface 221. The third reverse surface 222 is exposed from the sealing resin 40 and is an example of “reverse surface”. The third end surface 223 is connected to the third obverse surface 221 and the third reverse surface 222 and faces in the x direction. The third end surface 223 is exposed from the sealing resin 40. The third end surface 223 and the first end surfaces 121 of the first leads 10 are aligned with each other in the y direction. In the illustrated example, each third lead 22 has the third obverse surface 221 that is larger in area than the third reverse surface 222.

The third leads 22 may be plated with Sn to cover the third reverse surfaces 222 and the third end surfaces 223, which are exposed from the sealing resin 40. Instead of the Sn plating, plating with a plurality of metals, such as Ni, Pd and Au stacked in the stated order, may be used.

As shown in FIGS. 9 to 15, the semiconductor element 30 is supported on the first leads 10A, 10B and 10C, the second leads 21 and the third leads 22. The semiconductor element 30 is covered with the sealing resin 40. The semiconductor element 30 includes a semiconductor substrate 31, a semiconductor layer 32, a plurality of first electrodes 33A, a plurality of second electrodes 33B, a passivation film 34 and a surface protective film 35. The first electrodes 33A and the second electrodes 33B are examples of “electrode”. The semiconductor element 30 is a flip-chip mounted LSI having circuitry inside.

The semiconductor element 30 includes an element first surface 30a and an element second surface 30b. The element first surface 30a opposes the first obverse surfaces 101 of the first leads 10A, 10B and 10C, the second obverse surfaces 211 of the second leads 21 and the third obverse surfaces 221 of the third leads 22 in the z direction. The element second surface 30b faces away from the element first surface 30a in the z direction.

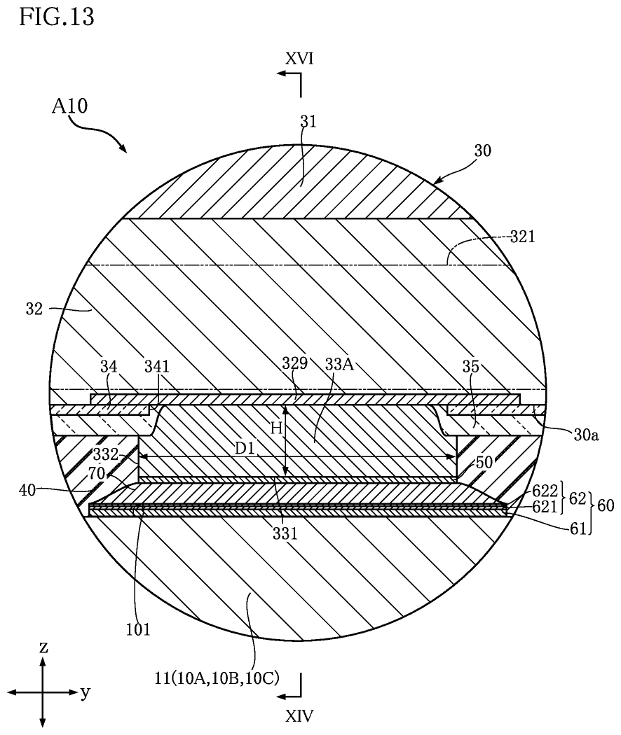

As shown in FIGS. 13 to 15, the semiconductor layer 32, the first electrodes 33A, the second electrodes 33B, the passivation film 34 and the surface protective film 35 are disposed below the semiconductor substrate 31. The semiconductor substrate 31 may be made of silicon (Si) or silicon carbide (SiC). In this embodiment, one side of the semiconductor substrate 31 forms the element second surface 30b.

As shown in FIGS. 9 to 12, the semiconductor layer 32 is disposed on the side of the semiconductor substrate 31 that opposes the first obverse surfaces 101 of the first leads 10 in the z direction. In this embodiment, one side of the semiconductor layer 32 forms the element first surface 30a. The semiconductor layer 32 may be made of any of a variety of types of p-type and n-type semiconductors depending on the amount of dopant. The semiconductor layer 32 defines a switching circuit 321 and a control circuit 322 electrically connected to the switching circuit 321. The switching circuit 321 may be a metal-oxide-semiconductor field-effect transistor (MOSFET) or an insulated gate bipolar transistor (IGBT), for example. In the example of the semiconductor device A10, the switching circuit 321 is divided into two regions, one of which is a high-voltage region (upper arum circuit) and the other is a low-voltage region (lower arm circuit). Each region is formed by one n-channel MOSFET. The control circuit 322, containing e.g., a gate driver for driving the switching circuit 321 and a bootstrap circuit for the high-voltage region of the switching circuit 321, is configured to control the switching circuit 321 to operate normally. The semiconductor layer 32 also defines a wiring layer (not shown). The wiring layer electrically connects the switching circuit 321 and the control circuit 322.

As shown in FIGS. 13 to 15, the semiconductor layer 32 is provided with a plurality of pads 329. The pads 329 are disposed in contact with the wiring layer defined by the semiconductor layer 32. Each pad 329 is thus electrically connected to one of the switching circuit 321 and the control circuit 322 defined by the semiconductor layer 32. The pads 329 may be composed of an Al layer or a plurality of metal layers of Cu, Ni and Pd stacked on the semiconductor layer 32 in the stated order downward.

As shown in FIGS. 13 to 15, the passivation film 34 covers the undersurface of the semiconductor layer 32 and portions of the pads 329. The passivation film 34 is electrically insulating. In one example, the passivation film 34 is formed by a film of silicon oxide (SiO₂) disposed in contact with the undersurface of the semiconductor layer 32 and the portions of the pads 329, and a film of silicon nitride (Si₃N₄) stacked on the silicon oxide film. The passivation film 34 has a plurality of openings 341 through which portions of the pads 329 are exposed. The passivation film 34 is not limited to a specific configuration.

As shown in FIGS. 13 to 15, the surface protective film 35 covers the passivation film 34. In the illustrated example, the surface protective film 35 is in contact with the first electrodes 33A and the second electrodes 33B. The surface protective film 35 is electrically insulating. The surface protective film 35 may be made of polyimide, for example. The surface protective film 35 is not limited to a specific configuration.

As shown in FIGS. 9 to 12, the first electrodes 33A and the second electrodes 33B are disposed on the side of the element first surface 30a in the z direction and project toward a corresponding one of the first obverse surfaces 101, the second obverse surfaces 211 and the third obverse surfaces 221. The first electrodes 33A and the second electrodes 33B are made of a Cu-containing material, such as Cu or a Cu alloy. According to this embodiment, the first electrodes 33A and the second electrodes 33B are in contact with the pads 329.

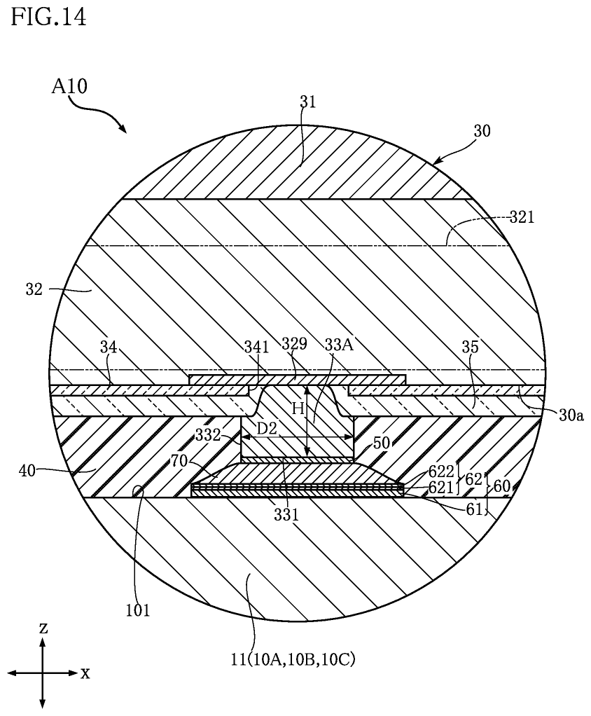

The first electrodes 33A are electrically connected to the switching circuit 321 defined by the semiconductor layer 32. Also, the first electrodes 33A are connected to the first obverse surface 101 of the first leads 10A, 10B and 10C. The first leads 10A, 10B and 10C are thus electrically connected to the switching circuit 321. The shape of the first electrodes 33A as viewed in the z direction is not limited and may be circular, elliptical (oval), rectangular or polygonal as desired. In the illustrated example, the first electrodes 33A are elliptical (oval) as viewed in the z direction. The dimensions of the first electrodes 33A are not limited. In one example, each first electrode 33A has a major diameter D1 of 300 μm, a minor diameter D2 of 100 μm, and a height H of 50 μm, as shown in FIGS. 13 and 14. In this example, the ratio of the height H to the major diameter D1 is 1:6, and the ratio of the height H to the minor diameter D2 is 1:2. The present disclosure, however, is not limited to such dimensions, and the ratio of the height H to the major diameter D1 or the minor diameter D2 may range from 1:2 to 1:10, for example.

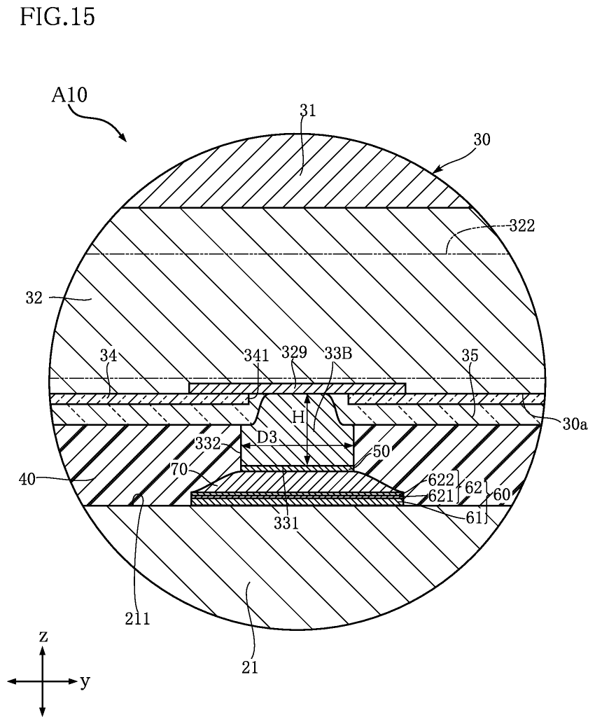

The second electrodes 33B are electrically connected to the control circuit 322 defined by the semiconductor layer 32. Most of the second electrodes 33B are connected to the second obverse surface 211 of the second leads 21, and the rest are connected to the third obverse surface 221 of the third leads 22. The second leads 21 and the third leads 22 are thus electrically connected to the control circuit 322. The shape of the second electrodes 33B as viewed in the z direction is not limited and may be circular, elliptical (oval), rectangular or polygonal as desired. In the illustrated example, the second electrodes 33B are circular as viewed in the z direction. The dimensions of the second electrodes 33B are not limited. In one example, each second electrode 33B has a diameter D3 of 100 μm and a height H of 50 μm as shown in FIG. 15. The ratio of the height H to the diameter D3 may range from 1:2 to 1:10, for example.

As shown in FIGS. 13 to 15, each of the first electrode 33A and the second electrodes 33B includes a distal end surface 331 and a lateral surface 332. The distal end surface 331 is the surface of the distal end of a first electrode 33A or a second electrode 33B in the z direction and opposes a corresponding one of the first obverse surfaces 101, the second obverse surfaces 211 and the third obverse surfaces 221. The distal end surface 331 is offset from the surface protective film 35 toward a corresponding one of the first obverse surfaces 101, the second obverse surfaces 211 and the third obverse surfaces 221 in the z direction. The lateral surface 332 extends from the distal end surface 331 toward a pad 329 (the semiconductor layer 32) and generally faces in a direction perpendicular to the z direction (i.e., in the x or y direction). The lateral surface 332 is in contact with the sealing resin 40. The distal end surface 331 and the lateral surface 332 are not limited to specific shapes. For example, the distal end surface 331 and/or the lateral surface 332 may be curved or bent or may have a recess.

As shown in FIGS. 13 to 15, the conductive bonding material 70 is disposed between the first obverse surface 101 of a relevant first lead 10A, 10B, 10C or the second obverse surface 211 of a relevant second lead 21 or the third obverse surface 221 of a relevant third lead 22 and a relevant first electrode 33A or a relevant second electrode 33B, thereby providing electrical connection between them. The conductive bonding material 70 is electrically conductive. For the semiconductor device A10, examples of the conductive bonding material 70 include solder containing Sn, solder containing indium, sintered Ag and Ag paste. This embodiment is directed to an example in which the conductive bonding material 70 is solder containing Sn.

As shown in FIGS. 13 to 15, a first barrier layer 50 is disposed between the conductive bonding material 70 and one of the first and second electrodes 33A and 33B and provides electrical connection between them. The first barrier layer 50 prevents the conductive bonding material 70 and the first electrode 33A or second electrode 33B from compounding with each other. The material of the first barrier layer 50 is not limited, and a suitable metal for preventing the reaction, such as Ni or Fe, can be selected. In the case where the first electrodes 33A and the second electrodes 33B contain Cu and the conductive bonding material 70 contains Sn, the first barrier layer 50 made of Ni is preferable. The thickness of the first barrier layer 50 may range from 0.3 to 5.0 μm for example, and preferably from 0.5 to 3.0 μm.

In this embodiment, the first barrier layer 50 is in contact with the distal end surface 331 of a first electrode 33A or a second electrode 33B and may be formed by plating the distal end surface 331. In one example, an additional conductive layer may be disposed between the distal end surface 331 and the first barrier layer 50. In this embodiment, the first barrier layer 50 is in contact with the conductive bonding material 70. To provide such a configuration, a layer containing Sn may be formed on the first barrier layer 50 by plating, and the Sn-contained layer may be melted and then solidified into the conductive bonding material 70 when the semiconductor element 30 is mounted on the first leads 10A, 10B, 10C, the second leads 21, and the third leads 22. An additional conductive layer of a different composition may be provided between the first barrier layer 50 and the conductive bonding material 70.

As shown in FIGS. 13 to 15, a second barrier layer 60 is disposed between the conductive bonding material 70 and the first obverse surface 101 of a relevant first lead 10A, 10B, 10C, or the second obverse surface 211 of a relevant second lead 21, or the third obverse surface 221 of a relevant third lead 22, thereby providing electrical connection between them. The second barrier layer 60 prevents the conductive bonding material 70 and the first lead 10A, 10B, 10C, or the second lead 21, or the third lead 22 from compounding with each other. The material of the second barrier layer 60 is not limited, and a suitable metal for preventing the compounding reaction, such as Ni or Fe, can be selected. In the illustrated example, the second barrier layer 60 is disposed to partly, rather than entirely, cover the first obverse surfaces 101, the second obverse surfaces 211 and the third obverse surfaces 221.

The second barrier layer 60 of this embodiment includes a base layer and an auxiliary layer 62. The base layer 61 is disposed between the auxiliary layer 62 and the first obverse surface 101 of a relevant first lead 10A, 10B, 10C, or the second obverse surface 211 of a relevant second lead 21, or the third obverse surface 221 of a relevant third lead 22. The base layer 61 is made of Ni, for example. The auxiliary layer 62 is stacked on the base layer 61 at its side opposite to the above-mentioned obverse surface, i.e., the first obverse surface 101 of the first lead 10A, 10B, 10C, or the second obverse surface 211 of the second lead 21, or the third obverse surface 221 of the third lead 22. In the illustrated example, the auxiliary layer 62 includes a first layer 621 and a second layer 622. The first layer 621 is stacked on the base layer 61. The second layer 622 is stacked on the first layer 621. The material of the first layer 621 is not limited and may include Pd, for example. The material of the second layer 622 is not limited and may include Au, for example.

The thicknesses of the base layer 61 and the auxiliary layer 62 are not limited. In one example, the base layer 61 may have a thickness ranging from 0.3 to 5.0 μm, and preferably from 0.5 to 3.0 μm. The first layer 621 of the auxiliary layer 62 may have a thickness ranging from 0.02 μm to 0.2 μm, for example. The second layer 622 may have a thickness ranging from 0.003 to 0.01 μm, for example.

In this embodiment, the second barrier layer 60 is in contact with one of the first obverse surfaces 101, the second obverse surfaces 211 and the third obverse surfaces 221. Additionally, another conductive layer may be provided between the second barrier layer 60 and the one of the first obverse surfaces 101, the second obverse surfaces 211 and the third obverse surfaces 221. In this embodiment, the second barrier layer 60 is in contact with the conductive bonding material 70. An additional conductive layer may be provided between the second barrier layer 60 and the conductive bonding material 70.

The shapes of the first and second barrier layers 50 and 60 as viewed in the z direction are not limited. In the examples shown in FIGS. 2, 3, 13 and 14, the first and second barrier layers 50 and 60 provided for the first electrodes 33A have an oval shape as viewed in the z direction. On the other hand, as shown in FIGS. 2, 3 and 15, the first and second barrier layers 50 and 60 provided for the second electrodes 33B have a circular shape as viewed in the z direction. As shown in FIGS. 13 to 15, the second barrier layer 60 is larger than the corresponding first barrier layer 50 as viewed in the z direction. That is, the first barrier layer 50 is contained within the second barrier layer 60 as viewed in the z direction. In the illustrated example, the second barrier layer 60 includes a second layer 622, and the second layer 622 is relatively wettable by the conductive bonding material 70. In this example, the conductive bonding material 70 is formed into a shape such that the cross sectional area in a direction perpendicular to the z direction is larger from the first barrier layer 50 toward the second barrier layer 60 in the z direction.

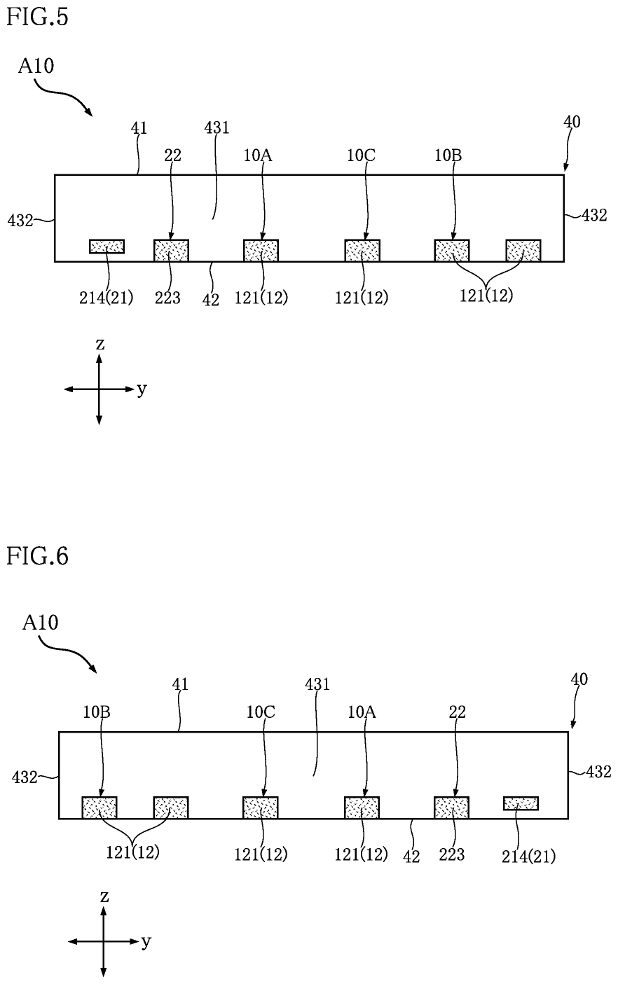

As shown in FIGS. 5 to 8, the sealing resin 40 includes a top surface 41, a bottom surface 42, a pair of first side surfaces 431 and a pair of second side surfaces 432. The sealing resin 40 may be made of a black epoxy resin.

As shown in FIGS. 9 to 12, the top surface 41 faces in the same direction as the first obverse surfaces 101 of the first leads 10A, 10B and 10C in the z direction. As shown in FIGS. 5 to 8, the bottom surface 42 faces away from the top surface 41. As shown in FIG. 4, the first reverse surfaces 102 of the first leads 10A, 10B and 10C, the second reverse surfaces 212 of the second leads 21 and the third reverse surfaces 222 of the third leads 22 are exposed on the bottom surface 42.

As shown in FIGS. 7 and 8, the pair of first side surfaces 431 are connected to the top surface 41 and the bottom surface 42 and face in the x direction. The pair of first side surfaces 431 are spaced apart from each other in the x direction. As shown in FIGS. 10 to 12, the first end surfaces 121 of the first leads 10A, 10B and 10C, the fourth end surfaces 214 of the second leads 21, and the third end surfaces 223 of the third lead 22 are flush with and exposed on the first side surfaces 431.

As shown in FIGS. 5 and 6, the pair of second side surfaces 432 are connected to the top surface 41, the bottom surface 42, and the pair of first side surfaces 431. The pair of second side surfaces 432 are spaced apart from each other in the x direction. As shown in FIG. 9, the second end surfaces 213 of the second leads 21 are flush with and exposed on the second side surface 432 that is located in the first sense of the y direction. The sub-end surfaces 131 of the first lead 10B are flush with and exposed on the second side surface 432 that is located in the second sense of the y direction.

The following describes advantages of the semiconductor device A10.

According to this embodiment, the first electrodes 33A and the second electrodes 33B are separated from the conductive bonding material 70 by the first barrier layer 50 interposed therebetween. Unlike this embodiment, suppose that the first electrodes 33A and the second electrodes 33B are disposed in contact with the conductive bonding material 70. In such a configuration, a reaction can occur between Cu contained in the first electrodes 33A and the second electrodes 33B and Sn contained in the conductive bonding material 70. As a result, pores, referred to as Kirkendall voids, may be formed at the joint interfaces of the first electrodes 33A and the second electrodes 33B with the conductive bonding material 70. Such a void may unduly be a starting point of a crack when the semiconductor device A10 is subjected to thermal stress. According to this embodiment, however, the first barrier layer 50 prevents the reaction between the first and second electrodes 33A and 33B and the conductive bonding material 70. This prevents the formation of voids at the joint interfaces between the first and second electrodes 33A and 33B and the conductive bonding material 70, and consequently reduces the occurrence of a crack.

When the first electrodes 33A and the second electrodes 33B contain Cu and the conductive bonding material 70 contain Sn, the first barrier layer 50 containing Ni is preferable for preventing a reaction between the first and second electrodes 33A and 33B and the conductive bonding material 70.

Providing the first barrier layer 50 in contact with the distal end surface 331 of each of the first electrodes 33A and the second electrodes 33B is preferable for preventing the undesired reaction. Providing the second barrier layer 60 in contact with the conductive bonding material 70 is preferable for preventing the undesired reaction.

According to this embodiment, the first leads 10A, 10B and 10C, the second leads 21 and the third leads 22 are separated from the conductive bonding material 70 by the second barrier layer 60 interposed therebetween. Unlike this embodiment, suppose that the first leads 10A, 10B and 10C, the second leads 21 and the third leads 22 are disposed in contact with the conductive bonding material 70. In such a configuration, a reaction can occur between Cu contained in the first leads 10A, 10B and 10C, the second leads 21 and the third leads 22 and Sn contained in the conductive bonding material 70. As a result, pores or Kirkendall voids may be formed at the joint interfaces of the first leads 10A, 10B and 10C, the second leads 21 and the third leads 22 with the conductive bonding material 70. Such a void may unduly be a starting point of a crack. According to this embodiment, however, the second barrier layer 60 prevents a reaction between the conductive bonding material 70 and the respective leads, i.e., the first leads 10A, 10B, 10C, the second leads 21, and the third leads 22. This prevents the formation of voids at the joint interfaces of the first leads 10A, 10B and 10C, the second leads 21 and the third leads 22 with the conductive bonding material 70 and consequently reduces the occurrence of a crack.

When the first leads 10A, 10B and 10C, the second leads 21 and the third leads 22 contain Cu and the conductive bonding material 70 contain Sn, the second barrier layer containing Ni is preferable for preventing a reaction between the conductive bonding material 70 and the respective leads, i.e., the first leads 10A, 10B,10C, the second leads 21, and the third leads 22. The second barrier layer 60 includes the base layer 61 containing Ni, and the base layer 61 is disposed directly on each of the first obverse surfaces 101, the second obverse surfaces 211 and the third obverse surfaces 221. Providing the second barrier layer 60 of such a configuration is preferable for preventing a reaction. Also, providing the second barrier layer 60 in contact with the conductive bonding material 70 is preferable for preventing a reaction.

The second barrier layer 60 includes the first layer 621 and the second layer 622. The second layer 622 containing Au improves the wettability of the second barrier layer 60 with respect to the conductive bonding material 70 in a molten state. Consequently, the conductive bonding material 70 can form to cover a larger area. Since the second barrier layer 60 is larger in area than the first barrier layer 50 as viewed in the z direction, the conductive bonding material 70 can be formed to cover a larger area on the side of the first obverse surface 101, the second obverse surface 211 and the third obverse surface 221 in comparison with the size of the first electrode 33A and the second electrode 33B.

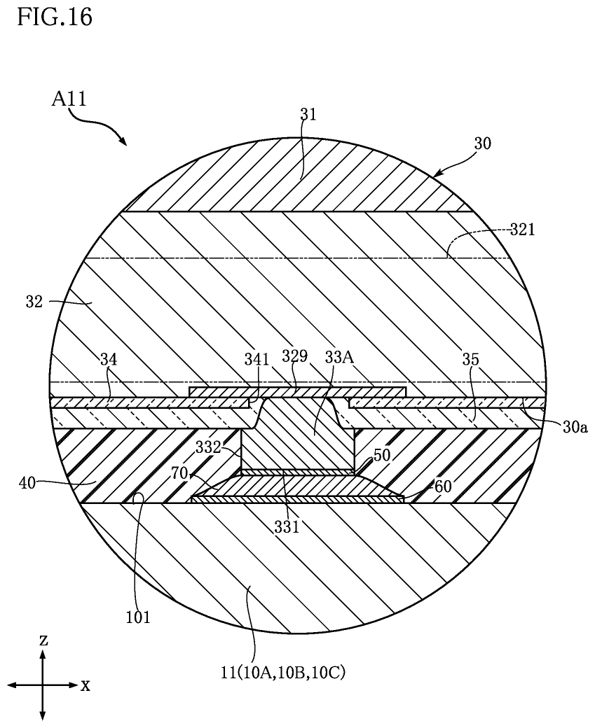

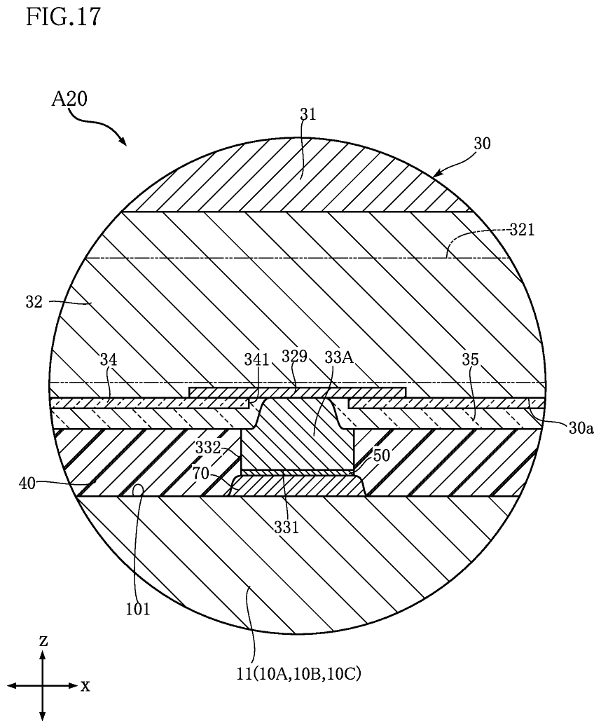

FIGS. 16 and 17 show a variation and another embodiment of the present disclosure. In these figures, the components similar or identical to those of the embodiment described above are denoted by the same reference numerals.

FIG. 16 shows a first variation of the semiconductor device A10. The semiconductor device All of this variation includes a second barrier layer 60 composed of a single layer. Specifically, the second barrier layer 60 is composed of a single layer of Ni, for example.

This variation can prevent the occurrence of a crack at the joint interfaces. As this variation demonstrates, the second barrier layer 60 is not limited to a multi-layer configuration.

FIG. 17 shows a semiconductor device according to a second embodiment. Unlike the first embodiment, the semiconductor device A20 of this embodiment is not provided with the second barrier layer 60.

According to this embodiment, the conductive bonding material 70 is disposed in contact with the first obverse surfaces 101. Alternatively, a plating layer may be disposed on the first obverse surfaces 101. When the conductive bonding material 70 is in contact with the first obverse surfaces 101 as in this embodiment, the bonding area between the conductive bonding material 70 and each first obverse surface 101 may be smaller than the bonding area between the conductive bonding material 70 and the second barrier layer 60 of the above-described embodiment.

According to this embodiment, the first barrier layer 50 prevents a reaction between the first and second electrodes 33A and 33B and the conductive bonding material 70. As seen from this embodiment, the second barrier layer 60 may be omitted depending on the usage environment and/or operating conditions of the semiconductor device A20.

The present disclosure is not limited to the foregoing embodiments and variation. Various design changes can be made to the specific construction of one or more components of the present disclosure.

### REFERENCE NUMERALS

A10, A11, A20: Semiconductor device
10, 10A, 10B, 10C: First lead
11: Main section
12: Side section
13: Projection
21: Second lead
22: Third lead
30: Semiconductor element
30a: Element first surface
30b: Element second surface
31: Semiconductor substrate
32: Semiconductor layer
33A: First electrode
33B: Second electrode
34: Passivation film
35: Surface protective film
40: Sealing resin
41: Top surface
42: Bottom surface
50: First barrier layer
60: Second barrier layer
61: Base layer
62: Auxiliary layer
70: Conductive bonding material
101: First obverse surface
102: First reverse surface
121: First end surface
131: Sub-end surface
211: Second obverse surface
212: Second reverse surface
213: Second end surface
214: Fourth end surface
221: Third obverse surface
222: Third reverse surface
223: Third end surface
321: Switching circuit
322: Control circuit
329: Pad
331: Distal end surface
332: Lateral surface
341: Opening
431: First side surface
432: Second side surface
621: First layer
622: Second layer

1. A semiconductor device comprising:
a semiconductor element including an element first surface and an element second surface facing away from each other in a thickness direction, the element first surface being provide with an electrode;
a conducting member including an obverse surface facing the element first surface and a reverse surface facing away from the obverse surface;
a conductive bonding material disposed between the electrode and the obverse surface of the conducting member;
a resin member that covers at least a portion of the conducting member, the semiconductor element and the conductive bonding material; and
a first barrier layer disposed between the electrode and the conductive bonding material and prevents a reaction between the electrode and the conductive bonding material.

2. The semiconductor device according to claim 1, wherein the electrode contains Cu.

3. The semiconductor device according to claim 1, wherein the conducting member contains Cu.

4. The semiconductor device according to claim 1, wherein the first barrier layer contains Ni.

5. The semiconductor device according to claim 1, wherein the conductive bonding material contains Sn.

6. The semiconductor device according to claim 1, wherein the electrode and the first barrier layer are in contact with each other.

7. The semiconductor device according to claim 1, wherein the conductive bonding material and the first barrier layer are in contact with each other.

8. The semiconductor device according to claim 1, further comprising a second barrier layer that is disposed between the conducting member and the conductive bonding material and prevents a reaction between the conducting member and the conductive bonding material.

9. The semiconductor device according to claim 8, wherein the second barrier layer contains Ni.

10. The semiconductor device according to claim 8, wherein the second barrier layer includes a base layer and an auxiliary layer disposed between the conductive bonding material and the base layer.

11. The semiconductor device according to claim 8, wherein the conducting member and the second barrier layer are in contact with each other.

12. The semiconductor device according to claim 8, wherein the conductive bonding material and the second barrier layer are in contact with each other.

13. The semiconductor device according to claim 8, wherein the second barrier is greater in length in a direction perpendicular to the thickness direction than the first barrier layer.

14. The semiconductor device according to claim 1, wherein the electrode includes a lateral surface facing in a direction perpendicular to the thickness direction.
